(19) United States
(12) Patent Application Publication
(10) Pub. No.: US 2014/0048950 A1
(43) Pub. Date: Feb. 20, 2014

(54) THERMALLY ENHANCED SEMICONDUCTOR ASSEMBLY WITH EMBEDDED SEMICONDUCTOR DEVICE AND BUILT-IN STOPPER AND METHOD OF MAKING THE SAME

(71) Applicant: BRIDGE SEMICONDUCTOR CORPORATION, Taipei City (TW)

(72) Inventors: Charles W.C. LIN, Singapore (SG); Chia-Chung WANG, Hsinchu (TW)

(73) Assignee: BRIDGE SEMICONDUCTOR CORPORATION, Taipei City (TW)

(21) Appl. No.: 13/753,589

(22) Filed: Jan. 30, 2013

Related U.S. Application Data
(63) Continuation-in-part of application No. 13/733,226, filed on Jan. 3, 2013.
Application No. 13/733,226 is a continuation-in-part of application No. 13/738,314, filed on Jan. 10, 2013.
(60) Provisional application No. 61/682,801, filed on Aug. 14, 2012.

(51) Int. Cl. H01L 23/34; H01L 21/50

(52) U.S. Cl. 257/774; 438/122

(57) ABSTRACT

The present invention relates to a thermally enhanced semiconductor assembly and a method of making the same. In accordance with one preferred embodiment, the method includes: forming a stopper on a metal layer; mounting a semiconductor device on the metal layer using the stopper as a placement guide for the semiconductor device; attaching a stiffener to the metal layer; forming a build-up circuitry that covers the stopper, the semiconductor device and the stiffener; providing a plated through-hole that provides an electrical connection between the build-up circuitry and the metal layer; and removing selected portions of the metal layer to form a thermal pad and a terminal. Accordingly, the thermal pad can provide excellent heat spreading, and the stopper can accurately confine the placement location of the semiconductor device and avoid the electrical connection failure between the semiconductor device and the build-up circuitry.

### CROSS REFERENCE TO RELATED APPLICATION

This application is a continuation-in-part of U.S. application Ser. No. 13/733,226 filed Jan. 3, 2013 and a continuation-in-part of U.S. application Ser. No. 13/738,314 filed Jan. 10, 2013, each of which is incorporated by reference. This application also claims the benefit of filing date of U.S. Provisional Application Ser. No. 61/682,801, entitled “Structure and Manufacture of Semiconductor Assembly and 3D Stacking thereof” filed Aug. 14, 2012 under 35 USC §119(e)(1).

U.S. application Ser. No. 13/733,226 filed Jan. 3, 2013 and U.S. application Ser. No. 13/738,314 filed Jan. 10, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a thermally enhanced semiconductor assembly and a method of making the same, and more particularly to a thermally enhanced semiconductor assembly with embedded stopper and semiconductor device and a method of making the same.

2. Description of Related Art

As market trend demands for thinner, smarter and cheaper portable electronics, semiconductor devices for use in these equipments are required to further shrink their size and improve electrical performances at lower cost. Among all the efforts, embedding or built-in semiconductor chip in printed wiring board to form a module assembly is considered the most effective approach since it can drastically reduce the overall weight, thickness and improve electrical performance through a shorten interconnect distance.

However, the attempt of embedding chip in a wiring board can encounter many problems. For example, the chip to be embedded is known to vertically and laterally shift during die attach and encapsulation/lamination processes due to thermal characteristics of plastic materials. The CTE mismatch between metal, dielectric and silicon at various stages of thermal treatment can result in misalignment of the build-up interconnect structure to be deposited thereon. U.S. Pat. No. 7,935,893 to Tanaka et. al., U.S. Pat. No. 7,944,039 to Aral and U.S. Pat. No. 7,405,103 to Chang disclose various alignment methods to address manufacturing yield concern. None of these approaches offers a proper solution or effective method for controlling die movement because the underneath adhesive will reflow during curing and therefore dislocates the attached die from the pre-determined location even a highly precise alignment mark and equipment are applied. U.S. Patent Application 2010/0184256 to Chino discloses a resin sealing method to fix the semiconductor device adhered to the adhesive layer formed on the support body. This approach may be effective in controlling die from further movement during sealing process, it does not provide any control or adjustment for die attach process and the mis-registration is unavoidable due to die attach adhesive reflows.

### SUMMARY OF THE INVENTION

The present invention has been developed in view of such a situation, and an object thereof is to provide a thermally enhanced semiconductor assembly in which a semiconductor device is precisely affixed at a predetermined location by a stopper, a thermal pad can provide a thermally conductive pathway, warp and bend of the semiconductor device can be suppressed, and electrical connection between the semiconductor device and the build-up circuitry can be securely retained by conductive via.

In one preferred embodiment, the present invention provides a method of making a thermally enhanced semiconductor assembly, which includes the following steps: forming a stopper on a metal layer; mounting a semiconductor device on the metal layer using the stopper as a placement guide for the semiconductor device that includes an active surface with a contact pad thereon and an inactive surface, wherein the active surface faces a first vertical direction, the inactive surface faces a second vertical direction opposite the first vertical direction and is attached to the metal layer, and the stopper extends from the metal layer in the first vertical direction and is located in close proximity to and laterally aligned with and laterally extends beyond peripheral edges of the semiconductor device in lateral directions orthogonal to the vertical directions; attaching a stiffener to the metal layer, including aligning the semiconductor device and the stopper within an aperture of the stiffener; forming a build-up circuitry that covers the stopper, the semiconductor device and the stiffener in the first vertical direction and includes a first conductive via that directly contacts the contact pad of the semiconductor device to provide an electrical connection between the semiconductor device and the build-up circuitry; providing a plated through-hole that extends through the stiffener in the vertical directions to provide an electrical connection between the build-up circuitry and the metal layer; and removing selected portions of the metal layer to form a thermal pad and a terminal, wherein the thermal pad extends beyond and covers the inactive surface of the semiconductor device in the second vertical direction and the terminal is spaced from the thermal pad and extends beyond the stiffener in the second vertical direction.

In another preferred embodiment, the present invention provides a method of making another thermally enhanced semiconductor assembly, which includes the following steps: forming a stopper on a metal layer; mounting a semiconductor device on the metal layer using the stopper as a placement guide for the semiconductor device that includes an active surface with a contact pad thereon and an inactive surface, wherein the active surface faces a first vertical direction, the inactive surface faces a second vertical direction opposite the first vertical direction and is attached to the metal layer, and the stopper extends from the metal layer in the first vertical direction and is located in close proximity to and laterally aligned with and laterally extends beyond peripheral edges of the semiconductor device in lateral directions orthogonal to the vertical directions; attaching a stiffener to the metal layer, including aligning the semiconductor device and the stopper within an aperture of the stiffener; and forming a build-up circuitry that covers the stopper, the semiconductor device and the stiffener in the first vertical direction and includes a first conductive via that directly contacts the contact pad of the semiconductor device to provide an electrical connection between the semiconductor device and the build-up circuitry.

The method of making a thermally enhanced semiconductor assembly according to the present invention can further include: forming a placement guide on the metal layer. Accordingly, attaching the stiffener to the metal layer can include: aligning the semiconductor device and the stopper within the aperture of the stiffener with the placement guide being in close proximity to and laterally aligned with and laterally extending beyond the outer peripheral edges of the stiffener in lateral directions.

Forming the stopper and the placement guide can include photolithographic process. By photolithography, the stopper and the placement guide can be designed into various patterns to avoid undesirable movement of the semiconductor device and the stiffener, thereby improving the manufacturing yield greatly.

The semiconductor device can be attached to the metal layer using an adhesive that contacts and is sandwiched between the semiconductor device and the metal layer. Likewise, the stiffener can be attached to the metal layer using an adhesive that contacts and is sandwiched between the stiffener and the metal layer. In any case, the adhesive can contact and be coplanar with the stopper and the placement guide in the second vertical direction and lower than the stopper and the placement guide in the first vertical direction. As a result, the semiconductor device can be affixed and mechanically connected to the metal layer at predetermined location defined by the stopper that extends from the metal layer and extends beyond the inactive surface of the semiconductor device in the first vertical direction. Likewise, the stiffener can be affixed and mechanically connected to the metal layer at predetermined location defined by the placement guide that extends from the metal layer and extends beyond the attached surface of the stiffener in the first vertical direction. As the adhesive is lower than the stopper and the placement guide in the first vertical direction, the stopper and the placement guide can stop the undesirable movement of the semiconductor device and the stiffener during curing the adhesive.

The build-up circuitry can include a first insulating layer and one or more first conductive traces. For instance, the first insulating layer covers the semiconductor device, the stopper and the stiffener in the first vertical direction and the first conductive traces extend from the first insulating layer in the first vertical direction. As a result, forming the build-up circuitry can include: providing a first insulating layer that covers the stopper, the semiconductor device and the stiffener in the first vertical direction; then forming one or more first via openings that extend through the first insulating layer and are aligned with one or more contact pads of the semiconductor device and optionally one or more additional first via openings that extend through the first insulating layer and are aligned with the stiffener; and then forming one or more first conductive traces that extend from the first insulating layer in the first vertical direction and extend laterally on the first insulating layer and extend through the first via openings and optionally the additional first via openings in the second vertical direction to form one or more first conductive vias in direct contact with the contact pads of the semiconductor device and optionally one or more additional first conductive vias in direct contact with the stiffener. Accordingly, the first conductive traces can directly contact the contact pads to provide signal routing for the semiconductor device, and thus the electrical connection between the semiconductor device and the build-up circuitry can be devoid of solder. The first conductive traces can also directly contact the stiffener for grounding or electrical connections to passive components such as thin film resistors or capacitors deposited thereon.

The build-up circuitry can further include additional insulating layers, additional via openings, and additional conductive traces if needed for further signal routing. For instance, the build-up circuitry can further include a second insulating layer, one or more second via openings and one or more second conductive traces. The second insulating layer can extend from the first insulating layer and the first conductive trace in the first vertical direction and can extend to peripheral edges of the interconnect substrate, and the second conductive traces extend from the second insulating layer in the first vertical direction. As a result, forming the build-up circuitry can further include: providing a second insulating layer on the first insulating layer and the first conductive trace that extends from the first insulating layer and the first conductive trace in the first vertical direction; then forming one or more second via openings that extend through the second insulating layer and are aligned with the first conductive trace; and then forming one or more second conductive traces that extend from the second insulating layer in the first vertical direction and extend laterally on the second insulating layer and extend through the second via openings in the second vertical direction to form one or more second conductive vias in direct contact with the first conductive traces, thereby electrically connecting the first conductive trace to the second conductive traces. The first via openings and the second via openings can have the same size, and the first insulating layer, the first conductive traces, the second insulating layer and the second conductive traces can have flat elongated surfaces that face in the first vertical direction.

The outmost conductive traces of the build-up circuitry can include one or more interconnect pads to provide electrical contacts for the next level assembly or another electronic device such as a semiconductor chip, a plastic package or another semiconductor assembly. The interconnect pads can include an exposed contact surface that faces in the first vertical direction. As a result, the next level assembly or another electronic device can be electrically connected to the embedded semiconductor device using a wide variety of connection media including gold or solder bumps on the electrical contacts (i.e. the interconnect pads of the build-up circuitry).

Providing the plated through-hole can include forming a through-hole that extends through the stiffener in the vertical directions, and then depositing a connecting layer on an inner sidewall of the through-hole.

The plated through-hole can be provided during providing the build-up circuitry. For instance, providing the plated through-hole can include forming a through-hole that extends through the stiffener and one or more insulating layers (e.g. extends through the first insulating layer, or extends through the first and second insulating layers) in the vertical directions after providing the insulating layers and then depositing a connecting layer on an inner sidewall of the through-hole during depositing the conductive traces (e.g. the first conductive trace or the second conductive trace).

The insulating layers can be deposited and extend to peripheral edges of the semiconductor assembly by numerous techniques including film lamination, roll coating, spin coating and spray-on deposition. The via openings can be formed through the insulating layers by numerous techniques including laser drilling, plasma etching and photolithography. The conductive traces can be formed by depositing a plated layer that covers the insulating layer and extends through the via opening and then removing selected portions of the plated layer using an etch mask that defines the conductive trace. The plated layers and the connecting layer can be deposited by numerous techniques including electroplating, electroless plating, evaporating, sputtering, and their combinations as a single layer or multiple layers. The plated layers and the metal layer can be patterned by numerous techniques including wet etching, electro-chemical etching, laser-assist etching, and their combinations to define the conductive traces, the terminal and the thermal pad.

By the above-mentioned method, the present invention can provide a thermally enhanced semiconductor assembly that includes: a thermal pad; a semiconductor device that is mounted on the thermal pad from a first vertical direction and includes an active surface with one or more contact pads thereon and an inactive surface, wherein the active surface faces the first vertical direction and the inactive surface faces a second vertical direction opposite the first vertical direction and is attached to the thermal pad; a stopper that extends from the thermal pad in the first vertical direction and serves as a placement guide for the semiconductor device and is in close proximity to and laterally aligned with and laterally extends beyond peripheral edges of the semiconductor device in lateral directions orthogonal to the vertical directions; a stiffener that includes an aperture with the semiconductor device and the stopper extending thereinto; and a build-up circuitry that covers the stopper, the semiconductor device and the stiffener in the first vertical direction and includes a first insulating layer, one or more first via openings and one or more first conductive traces, wherein the first via openings in the first insulating layer are aligned with the contact pads of the semiconductor device and optionally the stiffener, and the first conductive traces extend from the first insulating layer in the first vertical direction and extend through the first via openings in the second vertical direction and directly contact the contact pads and optionally the stiffener. Optionally, the semiconductor assembly can further include: a placement guide that is in close proximity to and laterally aligned with and laterally extends beyond the outer peripheral edges of the stiffener in lateral directions orthogonal to the vertical directions.

In accordance with one preferred embodiment, the semiconductor assembly can further include: a terminal that extends beyond the stiffener in the second vertical direction and is laterally with and spaced form the thermal pad; and a plated through-hole that extends through the stiffener to provide an electrical connection between the build-up circuitry and the terminal.

The stopper and the placement guide can have patterns against undesirable movement of the semiconductor device and the stiffener, respectively. For instance, the stopper and the placement guide can include a continuous or discontinuous strip or an array of posts. The stopper and the placement guide can be simultaneously formed and have the same or different patterns. Specifically, the stopper can be laterally aligned with four lateral surfaces of the semiconductor device to stop the lateral displacement of the semiconductor device. For instance, the stopper can be aligned along and conform to four sides, two diagonal corners or four corners of the semiconductor device and a gap in between the semiconductor device and the stopper preferably is in a range of about 0.001 to 1 mm. The semiconductor device can be spaced from the inner wall of the aperture by the stopper, and a bonding material can be added between the semiconductor device and the stiffener to enhance rigidity or the first insulating layer of the build-up circuitry may extend into and fill the gap between the semiconductor device and the stiffener. Moreover, the stopper can also be in close proximity to and laterally aligned with the inner wall of the aperture to stop the lateral displacement of the stiffener. Likewise, the placement guide can be laterally aligned with four outer lateral surfaces of the stiffener to stop the lateral displacement of the stiffener. For instance, the placement guide can be aligned along and conform to four outer sides, two outer diagonal corners or four outer corners of the stiffener and a gap in between the outer peripheral edges of the stiffener and the placement guide preferably is in a range of about 0.001 to 1 mm. Besides, the stopper and the placement guide preferably have a thickness in a range of 10-200 microns.

The thermal pad can be a thermally conductive metal plate such as copper with a thickness of 10-200 microns and can be spaced from or extend to peripheral edges of the assembly. In any case, the thermal pad can extend beyond and cover the inactive surface of the semiconductor device in the second vertical direction, and can have an exposed contact surface that faces the second vertical direction. Accordingly, the thermal pad can provide a thermally conductive pathway for the semiconductor device mounted thereon using an adhesive, thereby enhancing the thermal performance of the assembly. Furthermore, another electronic device can be mounted on the thermal pad and be electrically connected to the embedded semiconductor device by wire bonds or solder bumps, the terminal, the plated through-hole and the build-up circuitry.

The stiffener can extend to peripheral edges of the assembly and provide mechanical support to suppress warp and bend of the semiconductor device. Moreover, the stiffener also can provide ground/power plane and heat sink for the build-up circuitry. The stiffener can be a single layer structure or a multi-layer structure (such as a circuit board or a multi-layer ceramic board or a laminate of a substrate and a conductive layer). For instance, the stiffener can be made of ceramics or other various inorganic materials, such as aluminum oxide (Al₂O₃), aluminum nitride (AlN), silicon nitride (SiN), silicon (Si), glass, etc. The stiffener can also be made of organic materials such as laminated epoxy, polyimide or copper-clad laminate. Further, for the assembly without plated through-holes formed through the stiffener, the stiffener also can be made of copper (Cu), aluminum (Al), stainless steel etc.

The semiconductor device can be a packaged or unpackaged semiconductor chip. For instance, the semiconductor device can be a land grid array (LGA) package or wafer level package (WLP) that includes a semiconductor chip. Alternatively, the semiconductor device can be a semiconductor chip.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips.

Unless specific descriptions or using the term “then” between steps or steps necessarily occurring in a certain order, the sequence of the above-mentioned steps is not limited to that set forth above and may be changed or reordered according to desired design.

The present invention has numerous advantages. The stiffener can provide a power/ground plane, a heat sink and a robust mechanical support for the semiconductor device and the build-up circuitry. The stopper can accurately confine the placement location of the semiconductor device and avoid the electrical connection failure between the semiconductor device and the build-up circuitry resulted from the lateral displacement of the semiconductor device, thereby improving the manufacturing yield greatly. The thermal pad can include a selected portion of the metal layer thermally associated with the inactive surface of the embedded semiconductor device, thereby enhancing thermal performance. The direct electrical connection without solder between the semiconductor device and the build-up circuitry is advantageous to high I/O and high performance. The plated through-hole can provide vertical signal routing between the build-up circuitry and the terminal, thereby providing the assembly with stacking capability. The semiconductor assembly made by this method is reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional views showing a method of forming a stopper on a metal layer in accordance with an embodiment of the present invention;

FIG. 2A is a top view corresponding to FIG. 2;

FIGS. 2B-2F are top views of various stopper patterns that can be practiced in the present invention;

FIGS. 3 and 3A are cross-sectional and top views, respectively, of the structure with a semiconductor device mounted thereon in accordance with an embodiment of the present invention;

FIGS. 4 and 4A are cross-sectional and top views, respectively, of the structure with a stiffener mounted thereon in accordance with an embodiment of the present invention;

FIGS. 5-7 are cross-sectional views showing a method of making a semiconductor assembly that includes a semiconductor device, a stiffener, a stopper, a thermal pad and a build-up circuitry in accordance with an embodiment of the present invention;

FIGS. 8-10 are cross-sectional views showing a method of making another semiconductor assembly that includes a semiconductor device, a stiffener, a stopper, a thermal pad, a build-up circuitry, a terminal and a plated through-hole in accordance with another embodiment of the present invention;

FIG. 11 is a cross-sectional view showing a three dimensional stacked structure that includes a stackable semiconductor assembly and a semiconductor device attached to the build-up circuitry in accordance with an embodiment of the present invention;

FIG. 12 is a cross-sectional view showing a three dimensional stacked structure that includes a stackable semiconductor assembly and a semiconductor device attached to the thermal pad and the terminal in accordance with an embodiment of the present invention;

FIG. 13 is a cross-sectional view showing a three dimensional stacked structure that includes a stackable semiconductor assembly and a semiconductor device attached to the thermal pad in accordance with an embodiment of the present invention; and

FIGS. 14 and 14A are cross-sectional and top views, respectively, of yet another semiconductor assembly that includes a semiconductor device, a stopper, a placement guide, a stiffener, a thermal pad, a build-up circuitry, a terminal and a plated through-hole in accordance with yet another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

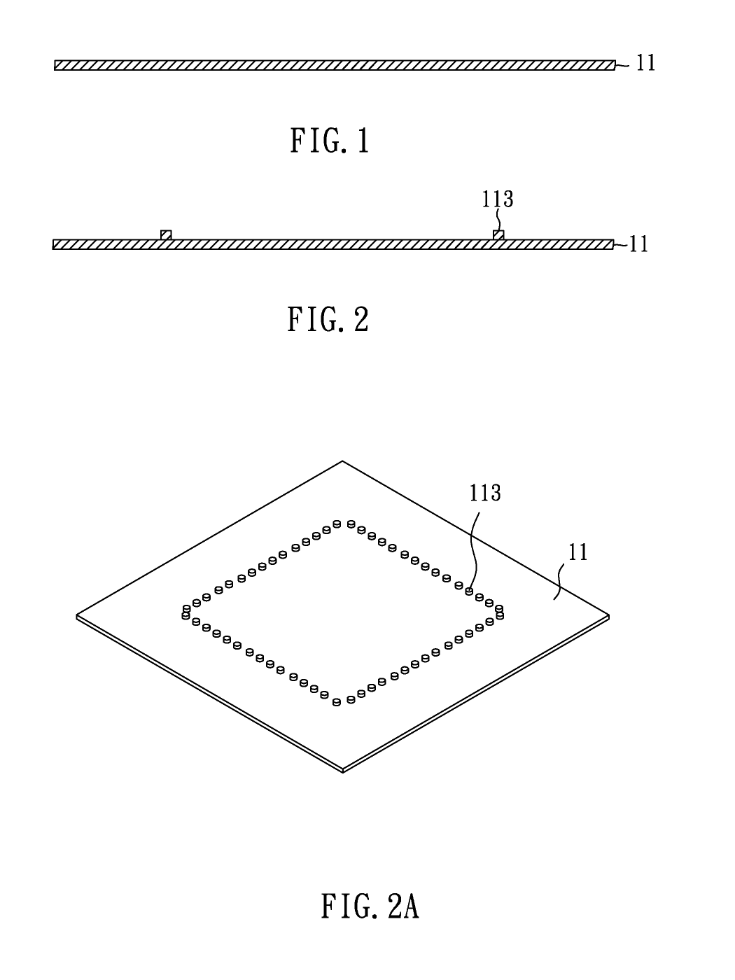

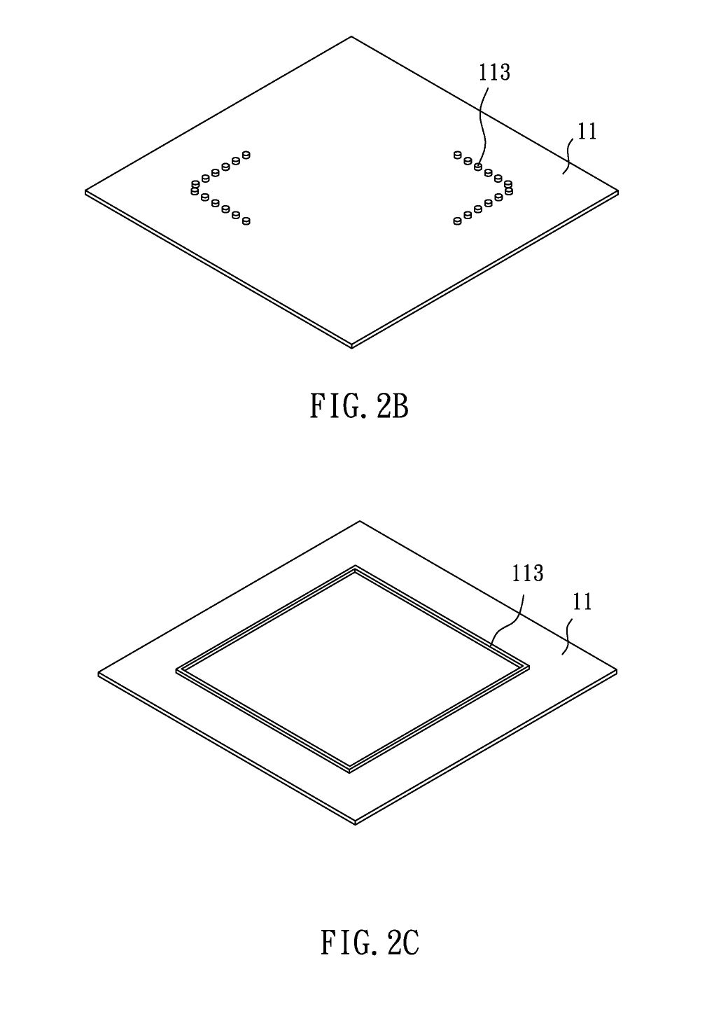

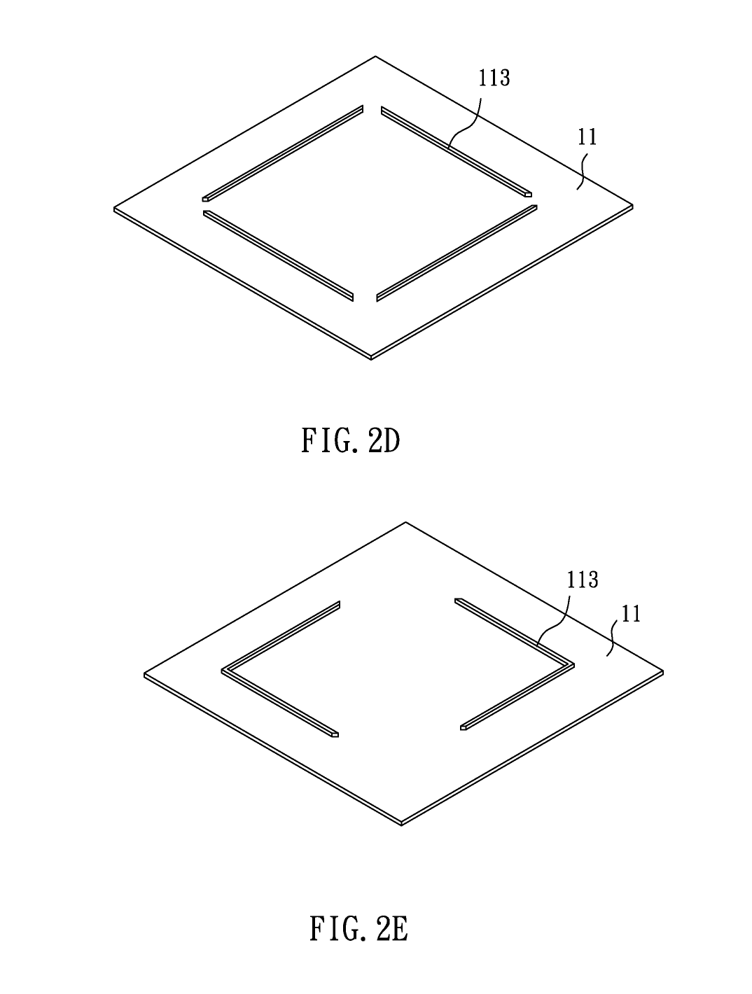

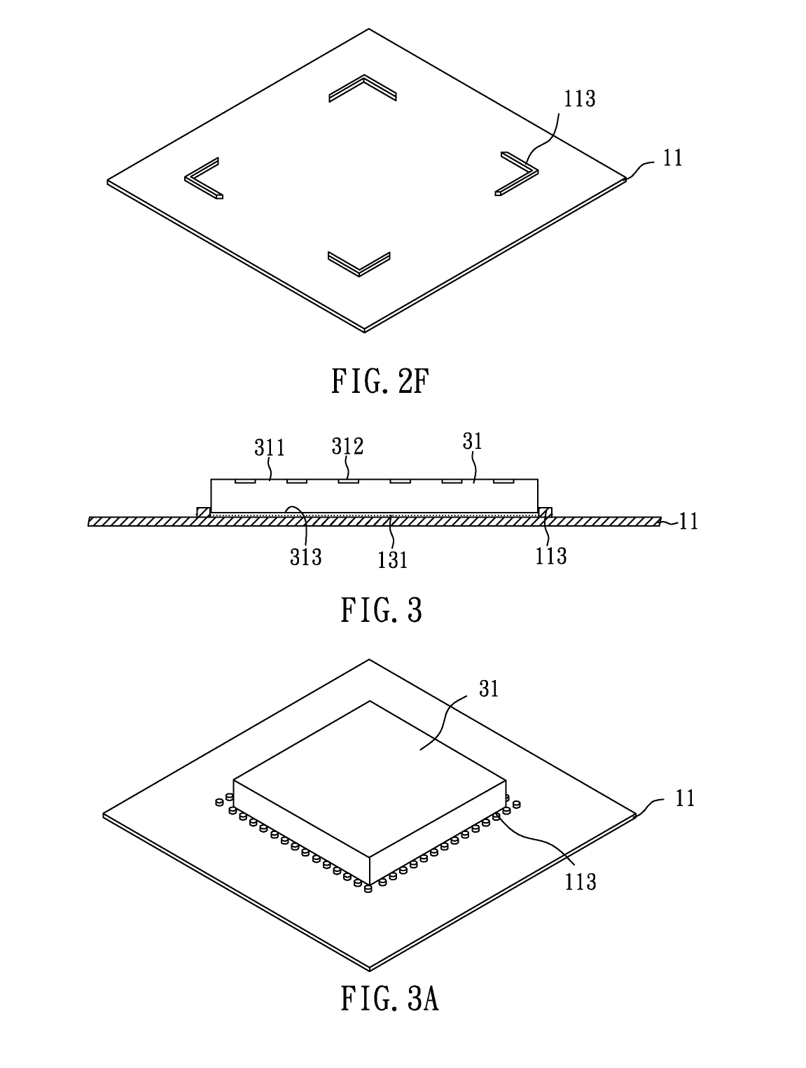

FIGS. 1 and 2 are cross-sectional views showing a method of forming a stopper on a metal layer in accordance with an embodiment of the present invention, and FIG. 2A is a top view corresponding to FIG. 2.

FIG. 1 is a cross-sectional view of metal layer 11. Metal layer 11 is illustrated as a copper layer with a thickness of 35 microns. Copper has high thermal conductivity and low cost. However, metal layer 11 can also be made of other various metal materials and is not limited to a copper layer. Besides, metal layer 11 preferably has a thickness in a range of 10 to 200 microns.

FIGS. 2 and 2A are cross-sectional and top views, respectively, of the structure with stopper 113 formed on metal layer 11. Stopper 113 can be formed by electrolytic plating of metal on metal layer 11 using photolithographic process. In this illustration, stopper 113 consists of plural metal posts in a rectangular frame array with a thickness of 35 microns and conforms to four sides of a semiconductor device subsequently disposed on metal layer 11. However, stopper patterns are not limited thereto and can be other various patterns against undesirable movement of the subsequently disposed semiconductor device.

FIGS. 2B-2F are top views of other various stopper patterns for reference. For instance, as shown in FIG. 2B, stopper 113 may conform to two diagonal corners of a subsequently disposed semiconductor device. Alternatively, as shown in FIGS. 2C-2F, stopper 113 may consist of a continuous or discontinuous strip and conform to four sides (FIGS. 2C and 2D), two diagonal corners (FIG. 2E) or four corners (FIG. 2F) of a subsequently disposed semiconductor device.

FIGS. 3-7 are cross-sectional views showing a method of making a semiconductor assembly that includes a semiconductor device, a stopper, a stiffener, a thermal pad and build-up circuitry in accordance with an embodiment of the present invention.

As shown in FIG. 7, semiconductor assembly 101 includes semiconductor device 31, stopper 113, thermal pad 114, stiffener 41 and build-up circuitry 201. Semiconductor device 31 includes active surface 311, inactive surface 313 opposite to active surface 311 and contact pads 312 at active surface 311, and is mounted on thermal pad 114. Build-up circuitry 201 is electrically connected to contact pads 312 of semiconductor device 31 and includes first insulating layer 211 and first conductive traces 231. Stopper 113 extends from thermal pad 114 in the upward direction and is in close proximity to peripheral edges of semiconductor device 31. Stopper 113 as well as semiconductor device 31 are aligned with and extend into aperture 411 of stiffener 41.

FIGS. 3 and 3A are cross-sectional and top views, respectively, of the structure with semiconductor device 31 such as a semiconductor chip mounted on metal layer 11 using adhesive 131. Semiconductor device 31 includes active surface 311, inactive surface 313 opposite to active surface 311, and contact pads 312 at active surface 311.

Stopper 113 can serve as a placement guide for semiconductor device 31, and thus semiconductor device 31 is precisely placed at a predetermined location with its inactive surface 313 facing metal layer 11. Stopper 113 extends from metal layer 11 beyond inactive surface 313 of semiconductor device 31 in the upward direction and is laterally aligned with and laterally extends beyond four sides of semiconductor device 31 in the lateral directions. As stopper 113 is in close proximity to and conforms to four lateral surfaces of semiconductor device 31 in lateral directions and adhesive 131 under semiconductor device 31 is lower than stopper 113, any undesirable movement of semiconductor device 31 due to adhesive curing can be avoided. Preferably, a gap in between semiconductor device 31 and stopper 113 is in a range of about 0.001 to 1 mm.

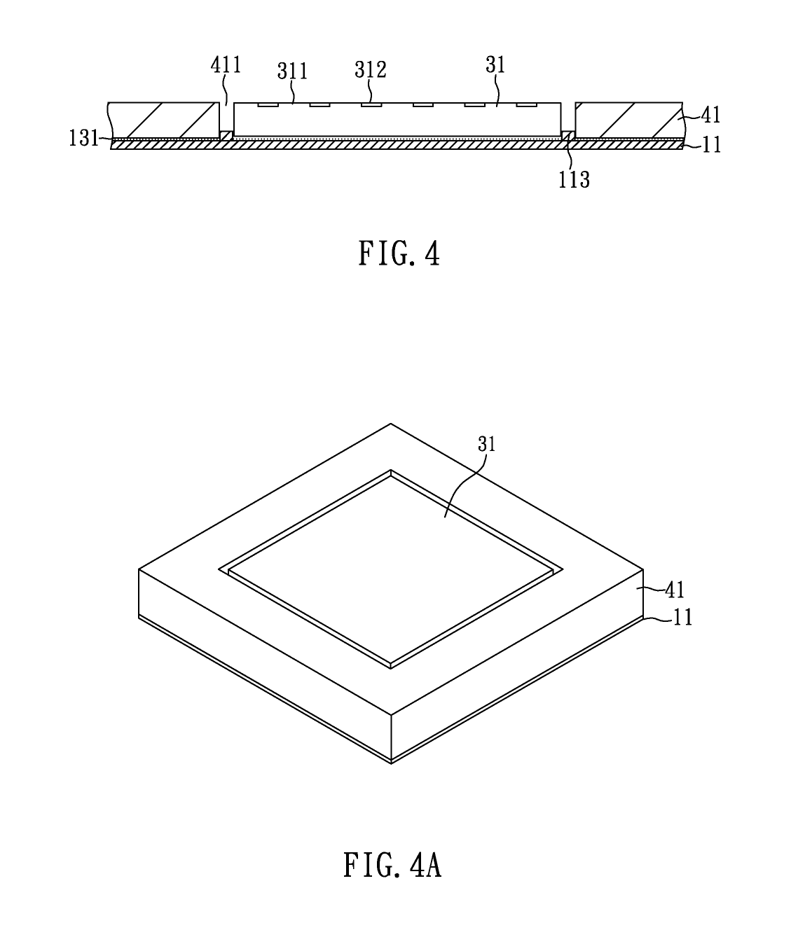

FIGS. 4 and 4A are cross-sectional and top views, respectively, of the structure with stiffener 41 mounted on metal layer 11 using adhesive 131. Semiconductor device 31 and stopper 113 are aligned with and inserted into aperture 411 of stiffener 41, and stiffener 41 is mounted on metal layer 11 using adhesive 131. Aperture 411 is formed by mechanical drilling through stiffener 41 and can be formed with other techniques such as punching and laser cutting. Stiffener 41 is illustrated as an epoxy sheet with a thickness of about the same to that of the semiconductor chip. The stiffener 41 can be other single layer such as metal, glass, ceramic or multi-layer laminate structures, such as a multi-layer circuit board.

Semiconductor device 31 and the inner wall of aperture 411 are spaced from one another by stopper 113. Stopper 113 is in close proximity to and laterally aligned with four inner walls of aperture 411 and adhesive 131 under stiffener 41 is lower than stopper 113, and thus any undesirable movement of stiffener 41 also can be avoided before adhesive 131 is fully cured. Optionally, a bonding material (not shown in the figure) can be added between semiconductor device 31 and stiffener 41 to enhance rigidity.

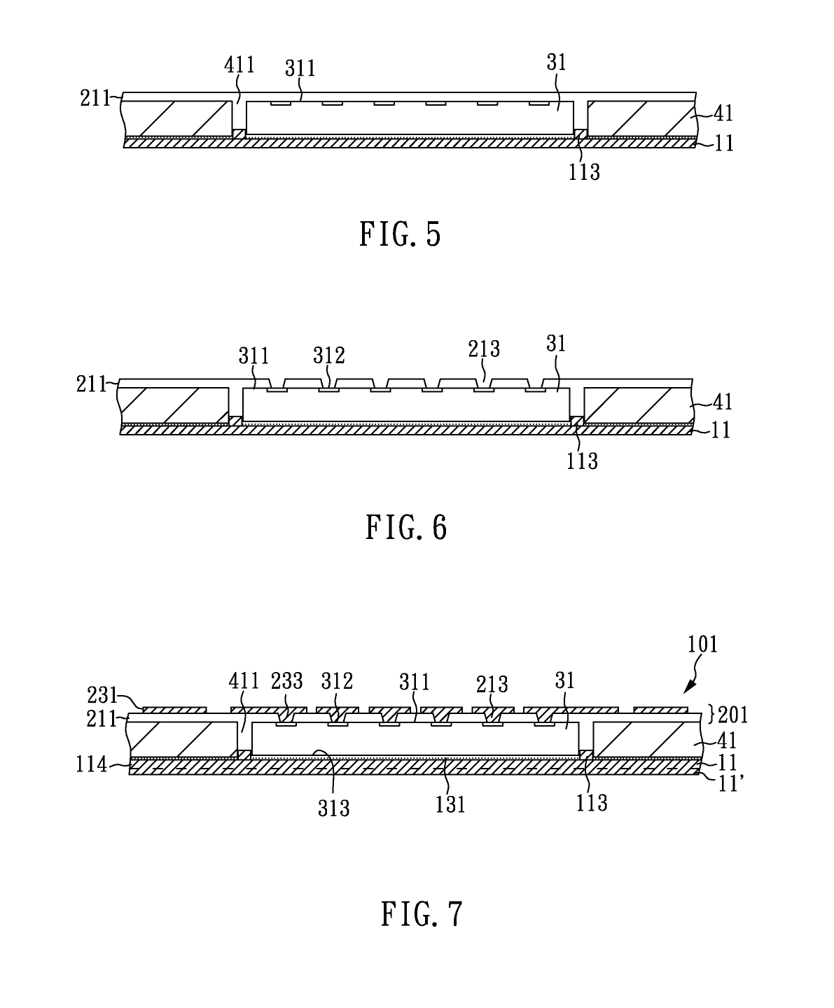

FIG. 5 is a cross-sectional view of the structure with first insulating layer 211 formed on active surface 311 of semiconductor device 31 and stiffener 41 in the upward direction. First insulating layer 211 covers semiconductor device 31, stiffener 41 and stopper 113 in the upward direction, and extends into the gap between semiconductor device 31 and stiffener 41 in aperture 411. First insulating layer 211 can be epoxy resin, glass-epoxy, polyimide and the like deposited by numerous techniques including film lamination, spin coating, roll coating, and spray-on deposition and typically has a thickness of 50 microns.

FIG. 6 is a cross-sectional view of the structure provided with first via openings 213. First via openings 213 extend through first insulating layer 211 to expose contact pads 312 of semiconductor device 31. First via openings 213 may be formed by numerous techniques including laser drilling, plasma etching and photolithography. Laser drilling can be enhanced by a pulsed laser. Alternatively, a scanning laser beam with a metal mask can be used. First via openings 213 typically have a diameter of 50 microns.

Referring now to FIG. 7, first conductive traces 231 are formed on first insulating layer 211 by depositing plated layer 11′ on first insulating layer 211 and into first via openings 213, and then patterning plated layer 11′. First conductive traces 231 extend from first dielectric layer 211 in the upward direction, extend laterally on first dielectric layer 211 and extend into first via openings 213 in the downward direction to form first conductive vias 233 in electrical contact with contact pads 312 of semiconductor device 31. Also, plated layer 11′ is further deposited on metal layer 11.

Plated layer 11′ can be deposited by numerous techniques including electroplating, electroless plating, evaporating, sputtering, and their combinations as a single layer or multiple layers. For instance, plated layer 11′ is deposited by first dipping the structure in an activator solution to render the insulating layer catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, plated layer 11′ can be patterned to form first conductive traces 231 by numerous techniques including wet etching, electro-chemical etching, laser-assist etching, and their combinations with an etch mask (not shown) thereon that defines first conductive traces 231.

Metal layer 11 and plated layer 11′ thereon are shown as a single layer for convenience of illustration. The boundary (shown in phantom) between the metal layers may be difficult or impossible to detect since copper is plated on copper. However, the boundary between plated layer 11′ and first insulating layer 211 is clear.

Accordingly, as shown in FIG. 7, semiconductor assembly 101 is accomplished and includes semiconductor device 31, stopper 113, stiffener 41, thermal pad 114 and build-up circuitry 201. In this illustration, build-up circuitry 201 includes first insulating layer 211 and first conductive traces 231. Metal layer 11 is used as thermal pad 114 for heat spreading and laterally extends from the area underneath semiconductor device 31 to peripheral edges of semiconductor assembly 101. Stopper 113 extends from metal layer 11 and extends beyond inactive surface 313 of semiconductor device 31 in the upward direction to accurately confine the placement location of semiconductor device 31. First conductive traces 231 extend from first insulating layer 211 in the upward direction, extend laterally on first insulating layer 211 and extend into via openings 213 in the downward direction to form first conductive vias 233 in electrical contact with contact pads 312, thereby providing signal routing for semiconductor device 31.

### Embodiment 2

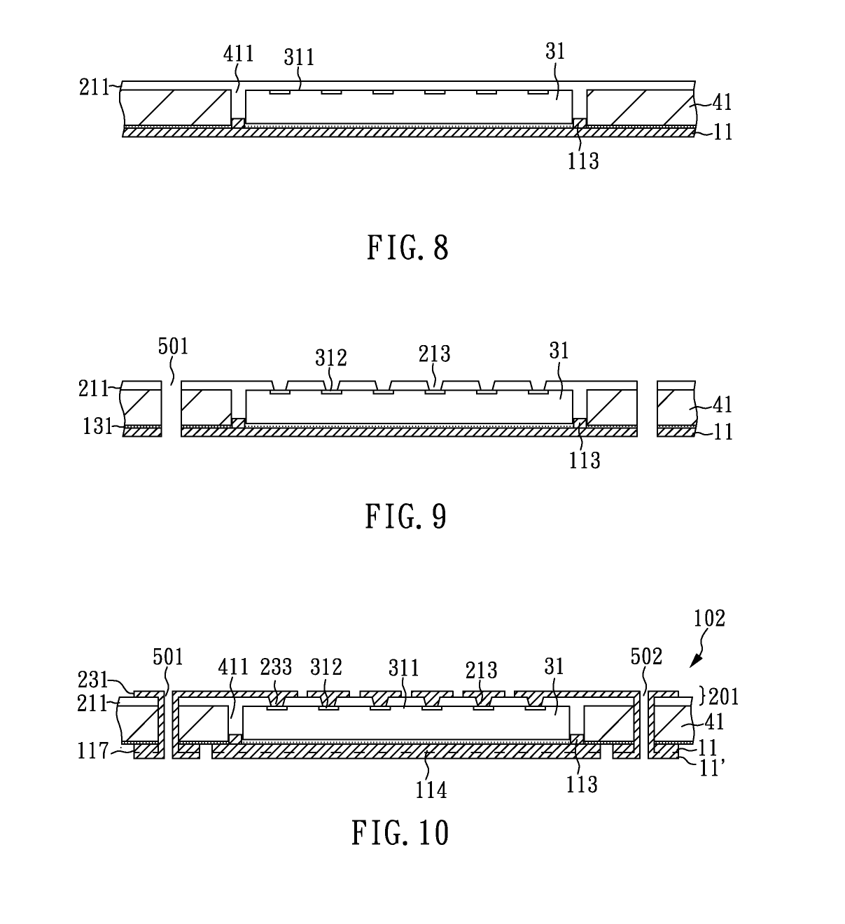

FIGS. 8-10 are cross-section views showing a method of making another semiconductor assembly that includes a semiconductor device, a stopper, a stiffener, a thermal pad, a build-up circuitry, a terminal and a plated through-hole in accordance with another embodiment of the present invention.

For purposes of brevity, any description in Embodiment 1 is incorporated herein insofar as the same is applicable, and the same description need not be repeated.

FIG. 8 is a cross-sectional view of the structure which is manufactured by the same steps shown in FIGS. 1-5.

FIG. 9 is a cross-sectional view of the structure provided with first via openings 213 and through-holes 501. First via openings 213 are aligned with and extend through first insulating layer 211 to expose contact pads 312 of semiconductor device 31. Through-holes 501 extend through first dielectric layer 211, stiffener 41, adhesive 131 and metal layer 11 in the vertical direction. Through-holes 501 are formed by mechanical drilling and can be formed by other techniques such as laser drilling and plasma etching with or without wet etching.

Referring now to FIG. 10, first conductive traces 231 and terminals 117 as well as thermal pad 114 are formed on two opposite sides of the assembly and are electrically connected to one another through plated through-holes 502. First conductive traces 231 are formed by depositing plated layer 11′ on first insulating layer 211 and into first via openings 213 and then patterning plated layer 11′, while thermal pad 114 and terminal 117 are formed by patterning metal layer 11 as well as plated layer 11′ thereon. Also, plated layer 11′ is further deposited as a connecting layer on the inner wall of through-holes 501 to provide plated through holes 502.

Accordingly, as shown in FIG. 10, semiconductor assembly 102 is accomplished and includes semiconductor device 31, stopper 113, stiffener 41, thermal pad 114, build-up circuitry 201, terminal 117 and plated through-holes 502. In this illustration, first build-up circuitry 201 includes first insulating layer 211 and first conductive traces 231. Thermal pad 114 extends beyond semiconductor device 31 and stopper 113 in the downward direction and is thermally connected with inactive surface 313 of semiconductor device 31, thereby providing thermally conductive pathway for semiconductor device 31. Stopper 113 extends from thermal pad 114 and extends beyond inactive surface 313 of semiconductor device 31 in the upward direction to accurately confine the placement location of semiconductor device 31. First conductive traces 231 extend from first insulating layer 211 in the upward direction, extend laterally on first insulating layer 211 and extend into via openings 213 in the downward direction to form first conductive vias 233 in electrical contact with contact pads 312, thereby providing signal routing for semiconductor device 31. Terminal 117 extends beyond stiffener 41 in the downward direction and is spaced from thermal pad 114. Plated through holes 502 extend through stiffener 41 in the vertical directions to provide electrical connection between first conductive traces 231 and terminal 117.

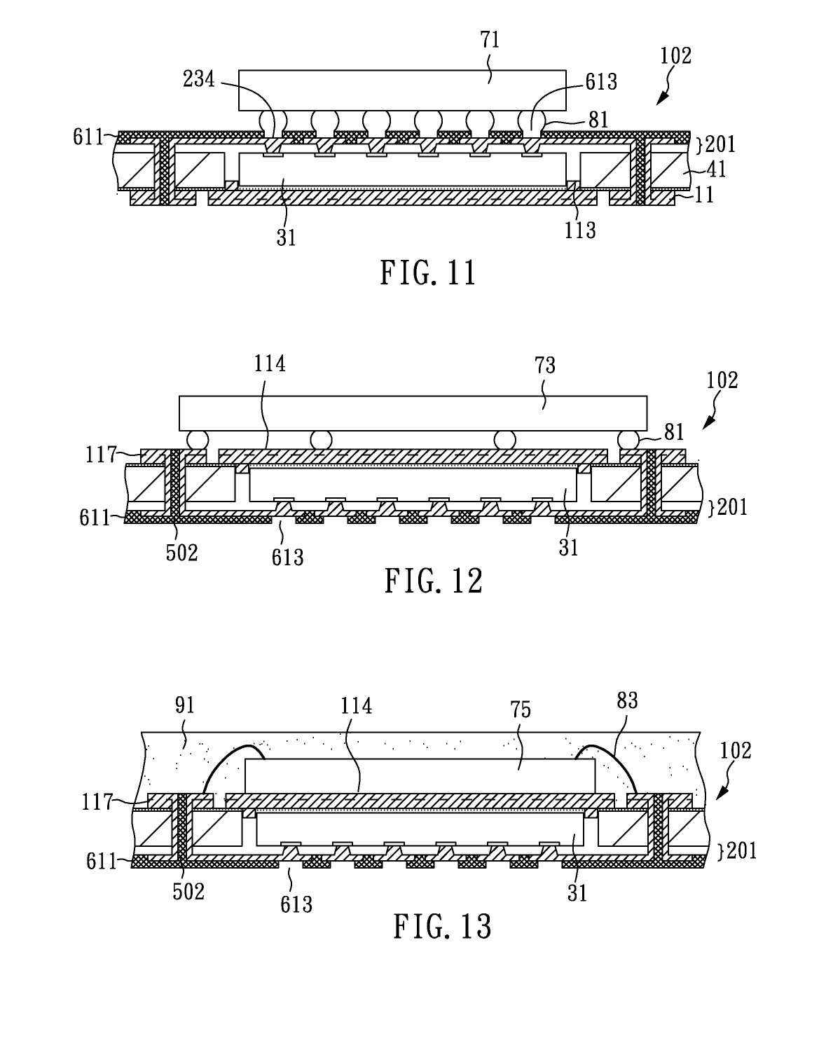

FIG. 11 is a cross-sectional view of a three-dimensional stacked structure in which another semiconductor device 71 is attached to the semiconductor assembly 102 at build-up circuitry 201 via solder bumps 81 on interconnect pads 234 exposed by solder mask material 611. In this illustration, solder mask material 611 is disposed over build-up circuitry 201 and includes solder mask openings 613 that are aligned with interconnect pads 234. External semiconductor device 71 can be electrically connected to the embedded semiconductor device 31 through solder bumps 81 and build-up circuitry 201. Herein, solder mask openings 613 may be formed by numerous techniques including photolithography, laser drilling and plasma etching, and solder bumps 81 can be provided by numerous techniques including screen printing solder paste followed by a reflow process or by electroplating.

FIG. 12 is a cross-sectional view of another three-dimensional stacked structure in which another semiconductor device 73 is attached to semiconductor assembly 102 at thermal pad 114 and terminal 117 via solder bumps 81. External semiconductor device 73 can be electrically connected to the embedded semiconductor device 31 through solder bumps 81, terminal 117, plated through-holes 502 and build-up circuitry 201.

FIG. 13 is a cross-sectional view showing yet another three-dimensional stacked structure in which another semiconductor device 75 is attached to semiconductor assembly 102 at thermal pad 114 and electrically connected to terminal 117 via wire bond 83. External semiconductor device 75 can be electrically connected to the embedded semiconductor device 31 through wire bond 83, terminal 117, plated through-holes 502 and build-up circuitry 201. Additionally, encapsulant 91 such as molding compound can be applied to protect semiconductor device 75 and wire bonds 83.

### Embodiment 3

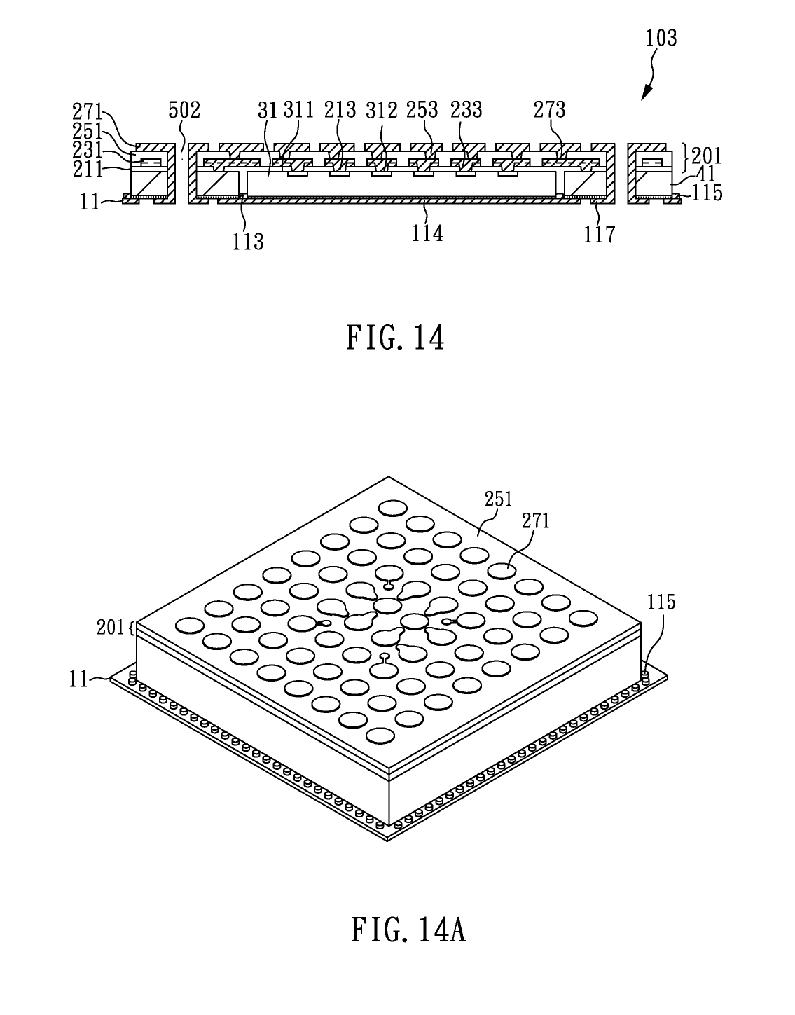

FIGS. 14 and 14A are cross-sectional and top views, respectively, of yet another semiconductor assembly 103 with placement guide 115 in close proximity to the outer peripheral edges of stiffener 41 and additional first conductive vias 233 in direct contact with stiffener 41 in accordance with yet another embodiment of the present invention.

In this embodiment, semiconductor assembly 103 is manufactured in a manner similar to that illustrated in Embodiment 2, except that placement guide 115 is simultaneously formed during stopper 113 formation to accurately confine the placement location of stiffener 41 and additional first conductive vias 233 are formed in direct contact with stiffener 41. Herein, first build-up circuitry 201 includes first insulating layer 211, first conductive traces 231, second insulating layer 251 and second conductive traces 271. First conductive traces 231 extends from first insulating layer 211 in the upward direction and extends into first via openings 213 in the downward direction to form first conductive vias 233 in direct contact with contact pads 312 and stiffener 41. Second insulating layer 251 extends from and covers first insulating layer 211 and first conductive traces 231 in the upward direction. Second conductive traces 271 extends from second insulating layer 251 in the upward direction and extends into second via openings 253 in the downward direction to form second conductive vias 273 in direct contact with first conductive traces 231. Plated through-holes 502 extend through second insulating layer 251, first insulating layer 211, stiffener 41 and adhesive 131 in the vertical directions to provide an electrical connection between second conductive traces 271 and terminal 117.

As shown in FIG. 14A, the placement location of stiffener 41 is accurately confined by placement guide 115 that extends from metal layer 11 beyond the attached surface of stiffener 41 in the upward direction and is laterally aligned with and laterally extends beyond four outer lateral surfaces of stiffener 41 in the lateral directions. Placement guide 115 is illustrated as plural metal posts and conforms to four outer sides of stiffener 41 in lateral directions. However, placement guide 115 is not limited to the illustrated pattern and can be designed in other various patterns. As placement guide 115 is in close proximity to and conforms to four outer lateral surfaces of stiffener 41 in lateral directions and adhesive 131 under stiffener 41 is lower than placement guide 115, any undesirable movement of stiffener 41 due to adhesive curing can be avoided. Preferably, a gap in between the outer peripheral edges of stiffener 41 and placement guide 115 is in a range of about 0.001 to 1 mm.

The semiconductor assemblies described above are merely exemplary. Numerous other embodiments are contemplated. In addition, the embodiments described above can be mixed-and-matched with one another and with other embodiments depending on design and reliability considerations. For instance, the semiconductor assembly may include multiple sets of stoppers to accurately define the relative positions of multiple additional semiconductor devices, passive components or other electronic devices, and the build-up circuitry can include additional conductive traces to accommodate additional semiconductor devices, passive components or other electronic devices. Likewise, the stiffener can include multiple apertures to accommodate additional semiconductor devices, passive components or other electronic devices.

The semiconductor device can be a packaged or unpackaged chip. Furthermore, the semiconductor device can be a bare chip, LGA, or QFN, etc. The stopper can be customized for the semiconductor device. For instance, the stopper can have a pattern that defines a square or rectangular area with the same or similar topography as the semiconductor device. The external heat dissipation element can be attached to the thermal pad to extend the contact area and enhance the efficiency of the dissipation pathway for the semiconductor device.

The term “adjacent” refers to elements that are integral (single-piece) or in contact (not spaced or separated from) with one another. For instance, the first conductive trace is adjacent to the active surface but not the inactive surface.

The term “overlap” refers to above and extending within a periphery of an underlying element. Overlap includes extending inside and outside the periphery or residing within the periphery. For instance, in the position that the thermal pad faces the downward direction, the semiconductor device overlaps the thermal pad since an imaginary vertical line intersects the semiconductor device and the thermal pad, regardless of whether another element such as the adhesive is between the semiconductor device and the thermal pad and is intersected by the line, and regardless of whether another imaginary vertical line intersects the thermal pad but not the semiconductor device (beyond the aperture of the stiffener). Likewise, the adhesive overlaps the thermal pad, the stiffener overlaps the adhesive and the adhesive is overlapped by the stiffener. Moreover, overlap is synonymous with over and overlapped by is synonymous with under or beneath.

The term “contact” refers to direct contact. For instance, the conductive trace contacts the active surface but not the inactive surface.

The term “cover” refers to incomplete and complete coverage in a vertical and/or lateral direction. For instance, in the position that the thermal pad faces the downward direction, the thermal pad covers the semiconductor device in the downward direction regardless of whether another element such as the adhesive is between the semiconductor device and the thermal pad, and the build-up circuitry cover the semiconductor device in the upward direction.

The term “layer” refers to patterned and un-patterned layers. For instance, the metal layer can be an un-patterned blanket sheet before photolithography and wet etching. Furthermore, a layer can include stacked layers.

The terms “opening” and “aperture” and “hole” refer to a through hole and are synonymous. For instance, in the position that the thermal pad faces the downward direction, the semiconductor device is exposed by the stiffener in the upward direction when it is inserted into the aperture in the stiffener.

The term “inserted” refers to relative motion between elements. For instance, the semiconductor device is inserted into the aperture regardless of whether the stiffener is stationary and the semiconductor device moves towards the stiffener, the semiconductor device is stationary and the stiffener moves towards the semiconductor device or the semiconductor device and the stiffener both approach the other. Furthermore, the semiconductor device is inserted (or extends) into the aperture regardless of whether it goes through (enters and exits) or does not go through (enters without exiting) the aperture.

The phrase “aligned with” refers to relative position between elements regardless of whether elements are spaced from or adjacent to one another or one element is inserted into and extends into the other element. For instance, the stopper is laterally aligned with the semiconductor device since an imaginary horizontal line intersects the stopper and the semiconductor device, regardless of whether another element is between the stopper and the semiconductor device and is intersected by the line, and regardless of whether another imaginary horizontal line intersects the semiconductor device but not the stopper or intersects the stopper but not the semiconductor device. Likewise, the first via opening is aligned with the contact pads of the semiconductor device, and the semiconductor device and the stopper are aligned with the aperture.

The phrase “in close proximity to” refers to a gap between elements not being wider than the maximum acceptable limit. As known in the art, when the gap between the semiconductor device and the stopper is not narrow enough, the location error of the semiconductor device due to the lateral displacement of the semiconductor device within the gap may exceed the maximum acceptable error limit. Once the location error of the semiconductor device goes beyond the maximum limit, it is impossible to align the contact pad with a laser beam, resulting in the electrical connection failure between the semiconductor device and the build-up circuitry. According to the pad size of the semiconductor device, those skilled in the art can ascertain the maximum acceptable limit for a gap between the semiconductor device and the stopper through trial and error to prevent the electrical connection failure between the semiconductor device and the build-up circuitry. Thereby, the description “the stopper is in close proximity to the peripheral edges of the semiconductor device” means that the gap between the peripheral edges of the semiconductor device and the stopper is narrow enough to prevent the location error of the semiconductor device from exceeding the maximum acceptable error limit.

The phrase “mounted on” includes contact and non-contact with a single or multiple support element(s). For instance, the semiconductor device is mounted on the metal layer regardless of whether it contacts the metal layer or is separated from the metal layer by an adhesive.

The phrase “electrical connection” or “electrically connects” or “electrically connected” refers to direct and indirect electrical connection. For instance, the plated through-hole provides an electrical connection for first conductive trace regardless of whether it is adjacent to the first conductive trace or electrically connected to the first conductive trace by the second conductive trace.

The term “above” refers to upward extension and includes adjacent and non-adjacent elements as well as overlapping and non-overlapping elements. For instance, in the position that the thermal pad faces the downward direction, the stopper extends above, is adjacent to and protrudes from the thermal pad.

The term “below” refers to downward extension and includes adjacent and non-adjacent elements as well as overlapping and non-overlapping elements. For instance, in the position that the thermal pad faces the downward direction, the thermal pad extends below, is adjacent to and protrudes from the adhesive and the stopper in the downward direction. Likewise, the thermal pad extends below the semiconductor device even though it is not adjacent to the semiconductor device.

The “first vertical direction” and “second vertical direction” do not depend on the orientation of the assembly, as will be readily apparent to those skilled in the art. For instance, the active surface of the semiconductor device faces the first vertical direction and the inactive surface of the semiconductor device faces the second vertical direction regardless of whether the assembly is inverted. Likewise, the stopper is “laterally” aligned with the semiconductor device in a lateral plane regardless of whether the assembly is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the active surface of the semiconductor device faces the downward direction, and the first vertical direction is the upward direction and the second vertical direction is the downward direction in the position that the active surface of the semiconductor device faces the upward direction.

The semiconductor assembly according to the present invention has numerous advantages. The semiconductor assembly made by this method is reliable, inexpensive and well-suited for high volume manufacture. The stiffener provides the mechanical support, dimensional stability and controls the overall flatness and the thermal expansion of the build-up circuitry such that the semiconductor device can be securely connected to the build-up circuitry under thermal cycling even though the coefficient of thermal expansion (CTE) between them may be different. The direct electrical connection without solder between the semiconductor device and the build-up circuitry is advantageous to high I/O and high performance. Particularly, the stopper can accurately confine the placement location of the semiconductor device and avoid the electrical connection failure between the semiconductor device and the build-up circuitry resulted from the lateral displacement of the semiconductor device, thereby improving the manufacturing yield greatly. The assembly is especially well-suited for high power semiconductor devices and large semiconductor chips as well as multiple semiconductor devices such as small semiconductor chips in arrays which generate considerable heat and require excellent heat dissipation in order to operate effectively and reliably.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A method of making a thermally enhanced semiconductor assembly with an embedded device and a built-in stopper, comprising:
forming a stopper on a metal layer;
mounting a semiconductor device on the metal layer using the stopper as a placement guide for the semiconductor device that includes an active surface with a contact pad thereon and an inactive surface, wherein the active surface faces a first vertical direction, the inactive surface faces a second vertical direction opposite the first vertical direction and is attached to the metal layer, and the stopper extends from the metal layer in the first vertical direction and is located in close proximity to and laterally aligned with and laterally extends beyond peripheral edges of the semiconductor device in lateral directions orthogonal to the vertical directions;
attaching a stiffener to the metal layer, including aligning the semiconductor device and the stopper within an aperture of the stiffener;
forming a build-up circuitry that covers the stopper, the semiconductor device and the stiffener in the first vertical direction and includes a first conductive via that directly contacts the contact pad of the semiconductor device to provide an electrical connection between the semiconductor device and the build-up circuitry;
providing a plated through-hole that extends through the stiffener in the vertical directions to provide an electrical connection between the build-up circuitry and the metal layer; and
removing selected portions of the metal layer to form a thermal pad and a terminal, wherein the thermal pad extends beyond and covers the inactive surface of the semiconductor device in the second vertical direction and the terminal is spaced from the thermal pad and extends beyond the stiffener in the second vertical direction.

2. The method of claim 1, wherein the electrical connection between the semiconductor device and the build-up circuitry is devoid of solder.

3. The method of claim 1, wherein forming the stopper on the metal layer includes photolithographic process.

4. The method of claim 1, wherein the semiconductor device is attached to the metal layer using an adhesive that contacts and is sandwiched between the semiconductor device and the metal layer.

5. The method of claim 4, wherein the adhesive contacts and is coplanar with the stopper in the second vertical direction and is lower than the stopper in the first vertical direction.

6. The method of claim 1, wherein forming the build-up circuitry includes:
providing a first insulating layer that covers the stopper, the semiconductor device and the stiffener in the first vertical direction; then
forming a first via opening that extends through the first insulating layer and is aligned with the contact pad of the semiconductor device; and then
forming a first conductive trace that extends from the first insulating layer in the first vertical direction and extends laterally on the first insulating layer and extends through the first via opening in the second vertical direction to form the first conductive via in direct contact with the contact pad of the semiconductor device.

7. The method of claim 6, wherein forming the build-up circuitry includes:
forming an additional first via opening that extends through the first insulating layer and is aligned with the stiffener; and then
forming the first conductive trace that extends through the additional first via opening in the second vertical direction to form an additional first conductive via in direct contact with the stiffener.

8. The method of claim 1, wherein providing the plated through-hole includes:
forming a through-hole that extends through the stiffener in the vertical directions; and then
depositing a connecting layer on an inner sidewall of the through-hole.

9. The method of claim 1, wherein the stopper include a continuous or discontinuous strip or an array of posts.

10. The method of claim 1, wherein a gap in between the semiconductor device and the stopper is in a range of 0.001 to 1 mm.

11. The method of claim 1, wherein the stopper has a height in a range of 10 to 200 microns.

12. The method of claim 1, wherein the stiffener is a laminated epoxy or polyimide.

13. A method of making a thermally enhanced semiconductor assembly with an embedded device and a built-in stopper, comprising:
forming a stopper on a metal layer;
mounting a semiconductor device on the metal layer using the stopper as a placement guide for the semiconductor device that includes an active surface with a contact pad thereon and an inactive surface, wherein the active surface faces a first vertical direction, the inactive surface faces a second vertical direction opposite the first vertical direction and is attached to the metal layer, and the stopper extends from the metal layer in the first vertical direction and is located in close proximity to and laterally aligned with and laterally extends beyond peripheral edges of the semiconductor device in lateral directions orthogonal to the vertical directions;
attaching a stiffener to the metal layer, including aligning the semiconductor device and the stopper within an aperture of the stiffener; and
forming a build-up circuitry that covers the stopper, the semiconductor device and the stiffener in the first vertical direction and includes a first conductive via that directly contacts the contact pad of the semiconductor device to provide an electrical connection between the semiconductor device and the build-up circuitry.

14. A thermally enhanced semiconductor assembly with an embedded device and a built-in stopper, comprising:
a thermal pad;
a semiconductor device that is mounted on the thermal pad from a first vertical direction and includes an active surface with a contact pad thereon and an inactive surface, wherein the active surface faces the first vertical direction and the inactive surface faces a second vertical direction opposite the first vertical direction and is attached to the thermal pad;
the stopper that extends from the thermal pad in the first vertical direction and serves as a placement guide for the semiconductor device and is in close proximity to and laterally aligned with and laterally extends beyond peripheral edges of the semiconductor device in lateral directions orthogonal to the vertical directions;
a stiffener that includes an aperture with the semiconductor device and the stopper extending thereinto; and
a build-up circuitry that covers the stopper, the semiconductor device and the stiffener in the first vertical direction and includes a first insulating layer, a first via opening and a first conductive trace, wherein the first via opening in the first insulating layer is aligned with the contact pad of the semiconductor device, and the first conductive trace extends from the first insulating layer in the first vertical direction and extends through the first via opening in the second vertical direction and directly contacts the contact pad.

15. The thermally enhanced semiconductor assembly of claim 14, further comprising:
a terminal that extends beyond the stiffener in the second vertical direction and is laterally aligned with and spaced from the thermal pad; and
a plated through-hole that extends through the stiffener to provide an electrical connection between the build-up circuitry and the terminal.
